(19) United States
(12) Patent Application Publication
(10) Pub. No.: US 2024/0213744 A1
(43) Pub. Date: Jun. 27, 2024

(54) OPTICAL SEMICONDUCTOR ELEMENT

(71) Applicant: Mitsubishi Electric Corporation, Tokyo (JP)

(72) Inventor: Hiroyuki KAWAHARA, Tokyo (JP)

(73) Assignee: Mitsubishi Electric Corporation, Tokyo (JP)

(21) Appl. No.: 18/557,315

(22) PCT Filed: Jun. 17, 2021
(86) PCT No.: PCT/JP2021/022984

§ 371 Date: Oct. 26, 2023

(51) Int. Cl. H01S 5/343; H01S 5/227

(52) U.S. Cl. CPC H01S 5/34333; H01S 5/227

(57) ABSTRACT

An optical semiconductor element of the present disclosure includes: a first-conductivity-type semiconductor substrate; a stripe-shaped mesa structure including a laminate of a first-conductivity-type cladding layer, an active layer, and a second-conductivity-type first cladding layer layered on the first-conductivity-type semiconductor substrate; and a mesa buried layer including a semi-insulating first buried layer, a first-conductivity-type second buried layer, and a semi-insulating third buried layer doped with a transition metal, which are sequentially formed on both side surfaces of the mesa structure on the first-conductivity-type semiconductor substrate.

### TECHNICAL FIELD

The present disclosure relates to an optical semiconductor element and a method for manufacturing the same.

### BACKGROUND ART

In optical semiconductor elements represented by a semiconductor laser, a structure in which both side surfaces of an active layer are buried with a semiconductor for the purpose of current confinement to the active layer and heat dissipation from the active layer, that is, a so-called buried type semiconductor laser is often used. For InP (Indium Phosphide) based buried semiconductor lasers used for optical communication applications, broadband modulation frequency and improved light emission efficiency in a single semiconductor laser element are required in order to support higher capacity communication.

A combination of an n-type InP substrate and an InP buried layer doped with a semi-insulating material such as iron (Fe) is used in order to reduce capacitance of the semiconductor laser for the purpose of broadband modulation frequency and to improve the heat dissipation from the active layer for the purpose of increasing the light emission efficiency.

Fe acts as an acceptor that traps electrons in InP. On the other hand, since Fe has no trapping effect on holes, an element structure with an n-type InP buried layer in an upper part of the buried layer in contact with a p-type cladding layer is generally used. In such element structures, the n-type InP buried layer forms a barrier against holes in the p-type InP cladding layer.

### CITATION LIST

### Patent Document

Patent Document 1: Japanese Laid-Open Patent Publication No. 2004-047743

### SUMMARY OF THE INVENTION

### Problem to be Solved by the Invention

Unfortunately, in the above-described element structures, since a p-n junction region having a large area exists at the interface between the n-type InP buried layer and the p-type InP cladding layer, the CR time constant becomes large due to p-n junction capacitance, thereby causing a problem that cutoff frequency of the semiconductor laser is lowered. In applications requiring high-speed operation such as optical communication, there has been a problem that the operating bandwidth of the semiconductor laser is limited due to a decrease in the cutoff frequency. In addition, carrier recombination in the p-n junction region causes an increase in current leakage and thus a decrease in light emission efficiency of the semiconductor laser.

As means for reducing the area of the p-n junction region, a method of narrowing a mesa width of a mesa structure including the active layer of the semiconductor laser, a method of shortening the resonator of the semiconductor laser, or the like can be considered. Unfortunately, when the mesa width of the mesa structure is narrowed, there arises a new problem that heat dissipation property of the semiconductor laser deteriorates.

On the other hand, when the resonator of the semiconductor laser is shortened, the cutoff frequency is lowered due to an increase in the element resistance and the light emission efficiency is lowered due to a decrease in the volume of the active layer, so that the trade-off relationship between the operating bandwidth and the light emission efficiency cannot be eliminated. Assuming optical communication applications of 50 Gbps or higher, the element structure including the above-described p-n junction interface is difficult to deal with.

Although the electro-absorption modulator constituting a part of the optical integrated device described in Patent Document 1 is used for a different purpose from the semiconductor laser, as shown in FIG. 2b of Patent Document 1, the buried layer having a three-layer structure including the semi-insulating Fe-doped InP electron trapping layer, the n-type InP hole blocking layer, and the undoped InP layer is formed on both side surfaces of the mesa structure.

That is, the undoped InP layer is provided between the n-type InP hole blocking layer and the p-type InP cladding layer. When such a layered structure is applied as the buried layer of the semiconductor laser, the p-n junction capacitance can be reduced due to the presence of the undoped InP layer. Unfortunately, since such a layered structure is a p-i-n structure, the carrier recombination at that portion cannot be suppressed, and the problem of a decrease in light emission efficiency has not yet been solved.

It is an object of the present disclosure to provide an optical semiconductor element and a method for manufacturing the optical semiconductor element that enable high-speed modulation by reducing the p-n junction capacitance caused by the p-n junction region formed between the buried layer and the second-conductivity-type cladding layer and that enable high light emission efficiency by suppressing the carrier recombination at the interface between the buried layer and the second-conductivity-type cladding layer.

### Means to Solve the Problem

An optical semiconductor element according to the present disclosure includes: a first-conductivity-type semiconductor substrate; a stripe-shaped mesa structure including a laminate of a first-conductivity-type cladding layer, an active layer, and a second-conductivity-type first cladding layer layered on the first-conductivity-type semiconductor substrate; and a mesa buried layer including a semi-insulating first buried layer, a first-conductivity-type second buried layer, and a semi-insulating third buried layer doped with a transition metal, which are sequentially formed on both side surfaces of the mesa structure on the first-conductivity-type semiconductor substrate.

A method for manufacturing an optical semiconductor element according to the present disclosure includes: a first crystal growth step of sequentially crystal-growing a first-conductivity-type cladding layer, an active layer, and a second-conductivity-type first cladding layer on a first-conductivity-type semiconductor substrate by MOCVD; a mesa structure formation step of etching the first-conductivity-type cladding layer, the active layer, the second-conductivity-type first cladding layer, and a part of the first-conductivity-type semiconductor substrate into a stripe-shaped mesa structure; a second crystal growth step of sequentially crystal-growing a mesa buried layer including a semi-insulating first buried layer, a first-conductivity-type second buried layer, and a semi-insulating third buried layer doped with one or more transition metals on both side surfaces of the mesa structure on the first-conductivity-type semiconductor substrate by MOCVD; and a third crystal growth step of sequentially crystal-growing, so as to be layered, a second-conductivity-type second cladding layer and a second-conductivity-type contact layer on a top surface of the mesa structure and a surface and a part of side surfaces of the mesa buried layer by MOCVD.

### Effect of the Invention

According to the optical semiconductor element and method for manufacturing the same of the present disclosure, it is possible to reduce the p-n junction capacitance caused by the p-n junction formed between the mesa buried layer and the second-conductivity-type cladding layer. In addition, the carrier recombination at the interface between the mesa buried layer and the second-conductivity-type cladding layer can be suppressed. Therefore, it is possible to achieve high-speed modulation and high light emission efficiency of the optical semiconductor element. In addition, the optical semiconductor element can be easily manufactured.

### BRIEF DESCRIPTION OF THE DRAWINGS

FIG. 1 is a cross-sectional view showing an element structure of an optical semiconductor element according to Embodiment 1.

FIG. 2 is a cross-sectional view showing a method for manufacturing an optical semiconductor element according to Embodiment 1.

FIG. 3 is a cross-sectional view showing the method for manufacturing an optical semiconductor element according to Embodiment 1.

FIG. 4 is a cross-sectional view showing the method for manufacturing an optical semiconductor element according to Embodiment 1.

FIG. 5 is a cross-sectional view showing the method for manufacturing an optical semiconductor element according to Embodiment 1.

FIG. 6 is a cross-sectional view showing the method for manufacturing an optical semiconductor element according to Embodiment 1.

FIG. 7 is a cross-sectional view showing an element structure of an optical semiconductor element according to a comparative example.

FIG. 8 is a cross-sectional view showing an element structure of an optical semiconductor element according to Embodiment 2.

FIG. 9 is a cross-sectional view showing a method for manufacturing an optical semiconductor element according to Embodiment 2.

FIG. 10 is a cross-sectional view showing the method for manufacturing an optical semiconductor element according to Embodiment 2.

FIG. 11 is a cross-sectional view showing the method for manufacturing n optical semiconductor element according to Embodiment 2.

FIG. 12 is a cross-sectional view showing the method for manufacturing an optical semiconductor element according to Embodiment 2.

FIG. 13 is a cross-sectional view showing an element structure of an optical semiconductor element according to Embodiment 3.

FIG. 14 is a cross-sectional view showing a method for manufacturing an optical semiconductor element according to Embodiment 3.

FIG. 15 is a cross-sectional view showing the method for manufacturing an optical semiconductor element according to Embodiment 3.

FIG. 16 is a cross-sectional view showing an element structure of an optical semiconductor element according to Embodiment 4.

FIG. 17 is a cross-sectional view showing a method for manufacturing an optical semiconductor element according to Embodiment 4.

FIG. 18 is a cross-sectional view showing the method for manufacturing the optical semiconductor element according to Embodiment 4.

FIG. 19 is a cross-sectional view showing the method for manufacturing an optical semiconductor element according to Embodiment 4.

### DESCRIPTION OF EMBODIMENTS

### Embodiment 1

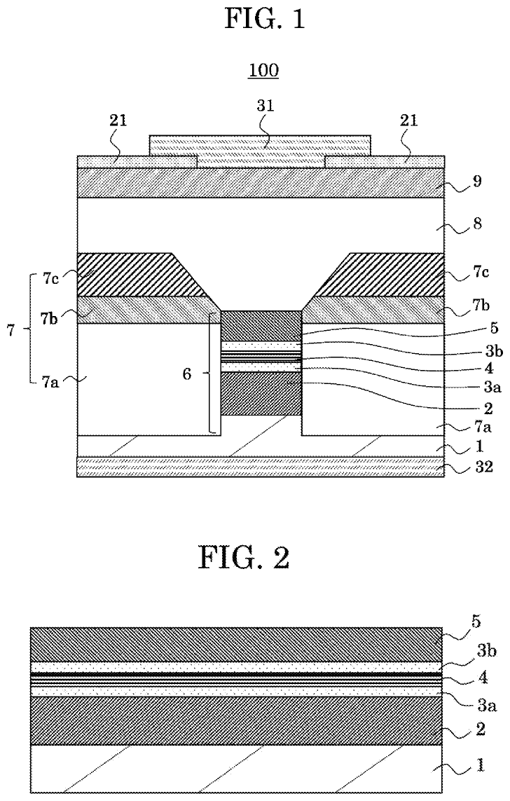

FIG. 1 is a cross-sectional view of an element structure of an optical semiconductor element 100 according to Embodiment 1. The optical semiconductor element 100 according to Embodiment 1 including: an n-type InP substrate 1 (a first-conductivity-type semiconductor substrate); a stripe-shaped mesa structure 6 including a laminate of an n-type InP cladding layer 2 (a first-conductivity-type cladding layer), a first optical confinement layer 3a, an active layer 4, a second optical confinement layer 3b, a p-type InP first cladding layer 5 (a second-conductivity-type first cladding layer), which are sequentially laminated on the n-type InP substrate 1, and a part of the n-type InP substrate 1; a mesa buried layer 7 including a semi-insulating InP first buried layer 7a (a semi-insulating first buried layer), an n-type InP second buried layer 7b (a first-conductivity-type second buried layer), and a semi-insulating InP third buried layer 7c (a semi-insulating third buried layer), which are formed on both side surfaces of the mesa structure 6 on the n-type InP substrate 1; a p-type InP second cladding layer 8 (a second-conductivity-type second cladding layer) and a p-type InGaAs contact layer 9 (a second-conductivity-type contact layer), which are formed so as to cover a top surface of the mesa structure 6 and a surface and a part of both side surfaces of the mesa buried layer 7; a p-side electrode 31 (a second-conductivity-type-side electrode) which is in contact with the p-type InGaAs contact layer 9 through an opening of an insulation film 21 formed on a surface of the p-type InGaAs contact layer 9; and an n-side electrode 32 (a first-conductivity-type-side electrode) formed on a rear surface of the n-type InP substrate 1.

The n-type InP substrate 1 is doped with sulfur (S) and has a surface of a (100) plane. The n-type InP cladding layer 2 is doped with S and has a typical layer thickness of 1.0 μm and a typical S doping concentration of 1.0×10¹⁸ cm⁻³.

The active layer 4 is made of AlGaInAs (Aluminum Gallium Indium Arsenide) and is undoped. A typical layer thickness of the active layer 4 is 0.3 μm. The first optical confinement layer 3a and the second optical confinement layer 3b provided above and below the active layer 4 are made of AlGaInAs and are undoped.

The p-type InP first cladding layer 5 is doped with zinc (Zn). A typical layer thickness of the p-type InP first cladding layer 5 is 0.3 μm and a typical doping concentration of Zn is 1.0×10¹⁸ cm⁻³.

The semi-insulating InP first buried layer 7a is doped with transition metals. Note that the transition metal is a generic name of elements existing between Group 3 elements and Group 11 elements in the periodic table. Specific examples of the transition metal include Fe, ruthenium (Ru), titanium (Ti), or the like. A typical layer thickness of the semi-insulating InP first buried layer 7a is 1.8 μm and a typical doping concentration of Fe is 5.0×10¹⁶ cm⁻³.

The n-type InP second buried layer 7b is doped with S. A typical layer thickness of the n-type InP second buried layer 7b is 0.2 μm, and a typical doping concentration of S is 5.0×10¹⁸ cm⁻³.

The semi-insulating InP third buried layer 7c is doped with the transition metals. Specific examples of the transition metal include Fe, Ru, and Ti, or the like. A typical layer thickness of the semi-insulating InP third buried layer 7c is 0.5 μm and a typical doping concentration of the transition metal is 5.0×10¹⁶ cm⁻³.

The p-type InP second cladding layer 8 is doped with Zn. A typical layer thickness of the p-type InP second cladding layer 8 is 2.0 μm and a typical doping concentration of Zn is 1.0×10¹⁸ cm⁻³.

The p-type InGaAs (Indium Gallium Arsenide) contact layer 9 is doped with Zn. A typical layer thickness of the p-type InGaAs contact layer 9 is 0.3 μm and a typical doping concentration of Zn is 1.0×10¹⁹ cm⁻³.

Hereinafter, the operation of the optical semiconductor element 100 according to Embodiment 1 will be described.

In order to emit laser light in the optical semiconductor element 100, a laser driving circuit is electrically connected to the p-side electrode 31 and the n-side electrode 32, and a forward bias is applied to the optical semiconductor element 100. The current injected from the p-side electrode 31 of the optical semiconductor element 100 by the forward bias flows to the mesa structure 6 through the p-type InGaAs contact layer 9, and thus the laser light is generated in the active layer 4.

On the other hand, even if the forward bias is applied to the mesa buried layer 7, no current flows through the mesa buried layer 7 because the semi-insulating InP first buried layer 7a and the semi-insulating InP third buried layer 7c are high-resistance layers. That is, the mesa buried layer 7 functions as a current blocking layer. As a result, the current injected into the optical semiconductor element 100 flows in a concentrated manner in the mesa structure 6 due to the effect of current confinement by the mesa buried layer 7 provided on both sides of the mesa structure 6 and functioning as the current blocking layer. Therefore, the optical semiconductor element 100 can emit the laser light with high efficiency with respect to the injection current due to the current confinement effect of the mesa buried layer 7.

Next, the characteristics of the element structure of the optical semiconductor element 100 according to Embodiment 1 will be described.

In the optical semiconductor element 100 according to Embodiment 1, the Fe-doped semi-insulating InP third buried layer 7c is provided between the S-doped n-type InP second buried layer 7b and the Zn-doped p-type InP second cladding layer 8. Consequently, in the optical semiconductor element 100 according to Embodiment 1, it is possible to prevent the generation of p-n junction capacitance brought about by the p-n junction inevitably generated at the interface between the S-doped n-type InP second buried layer 7b and the Zn-doped p-type InP second cladding layer 8 by the element structure in which above-mentioned two layers are in contact with each other as in an optical semiconductor element 200 of a comparative example to be described later. This is because the p-n junction is not formed at the interface between the Fe-doped semi-insulating InP third buried layer 7c and the p-type InP second cladding layer 8.

In the optical semiconductor element 100 according to Embodiment 1, since Fe doped in the semi-insulating InP third buried layer 7c functions as acceptors having deep trap levels for electrons, the carrier recombination can also be suppressed at the interface between the Fe-doped semi-insulating InP third buried layer 7c and the p-type InP second cladding layer 8.

Therefore, in the optical semiconductor element 100 according to Embodiment 1, the semi-insulating InP third buried layer 7c doped with, for example, Fe, which is one of transition metals, can prevent the problem of the element structure described in Patent Document 1, that is, the problem that the carrier recombination cannot be suppressed in the p-i-n junction region caused when the undoped InP layer is provided between the n-type InP hole blocking layer and the p-type InP cladding layer.

In the optical semiconductor element 100 according to Embodiment 1, if the layer thickness of the semi-insulating InP third buried layer 7c is set to be thicker than the layer thickness of a depletion layer formed with the n-type InP second buried layer 7b adjacent to the semi-insulating InP third buried layer 7c on the side of the n-type InP substrate 1, the trapping effect of Fe on electrons can be more effectively utilized, thus it is advantageous in suppressing the carrier recombination. If the layer thickness of the semi-insulating InP third buried layer 7c is set to be thicker than the layer thickness of a depletion layer formed by the semi-insulating InP third buried layer 7c and the p-type InP second cladding layer 8, the carrier recombination can be further suppressed. It is more effective to make the layer thickness of the semi-insulating InP third buried layer 7c thicker than any of the layer thicknesses of above-mentioned two depletion layers.

Even if the semi-insulating InP third buried layer 7c is doped with Ru or Ti, which is one of transition metals, instead of Fe, a deep level for trapping holes is formed as in the case where Fe is doped, so that the same effect as in the case where Fe is doped occurs. Furthermore, when Ru or Ti is used as a dopant, mutual diffusion between Ru or Ti itself and the p-type dopant can be reduced as compared with the case where Fe is doped. Consequently, when Ru or Ti is used as a dopant, a further effect is obtained in terms of capacitance reduction and suppression of the carrier recombination as compared with the case where Fe is doped.

Since both electrons and holes can be trapped by co-doping the semi-insulating InP third buried layer 7c with two or more of Fe, Ru, and Ti, the carrier recombination at the interface between the semi-insulating InP third buried layer 7c and the p-type InP second cladding layer 8 can be further suppressed. Furthermore, the suppression effect on the carrier recombination occurring at the interface between the semi-insulating InP third buried layer 7c and the p-type InP second cladding layer 8 can be further improved by applying a structure in which the semi-insulating InP third buried layer 7c has a two-layer structure, with an Fe-doped layer on the n-type InP second buried layer 7b side and a Ru-doped or Ti-doped layer on the p-type InP second cladding layer 8 side.

### A Method for Manufacturing the Optical Semiconductor Element 100 According to Embodiment 1

A method for manufacturing the optical semiconductor element 100 according to Embodiment 1 will be described below. The S-doped n-type InP cladding layer 2, the undoped AlGaInAs active layer 4 whose upper and lower surfaces are sandwiched between the AlGaInAs first optical confinement layer 3a and the AlGaInAs second optical confinement layer 3b, and the Zn-doped p-type InP first cladding layer 5 are sequentially crystal-grown on the S-doped n-type InP substrate 1 whose upper surface is the (100) plane by a crystal growth method such as a metalorganic chemical vapor deposition (MOCVD) (first crystal growth step). FIG. 2 shows a cross-sectional view of each layer after crystal growth.

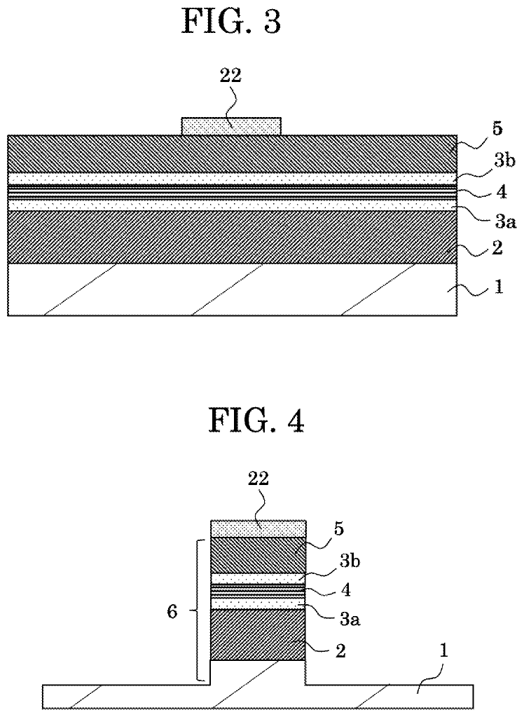

After the first crystal growth step, an SiO₂ film is formed on a surface of the p-type InP first cladding layer 5. As a method of forming the SiO₂ film, for example, a chemical vapor deposition (CVD) method or the like may be used. After the formation of the SiO₂ film, as shown in the cross-sectional view of FIG. 3, the SiO₂ film is patterned into a stripe-shaped SiO₂ mask 22 in the (011) direction by photolithography technique and etching technique. An example of the mask width of the SiO₂ mask 22 is 1.5 μm.

Next, as shown in the cross-sectional view of FIG. 4, the stripe-shaped SiO₂ mask 22 is used as an etching mask to perform dry etching from the p-type InP first cladding layer 5 to the middle of the n-type InP substrate 1, thereby forming the stripe-shaped mesa structure 6 (mesa structure formation step). A typical height of the mesa structure 6 from the surface of the n-type InP substrate 1 is 2.0 μm. Here, the etching mask is not limited to the SiO₂ mask 22 but may be a SiN mask. The etching is not limited to dry etching, and wet etching may be used.

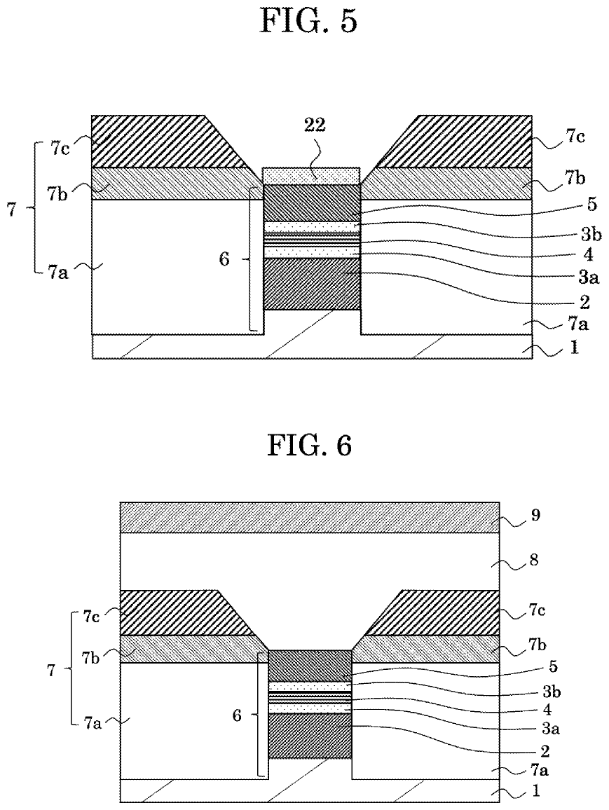

After the stripe-shaped mesa structure 6 is formed, as shown in the cross-sectional view of FIG. 5, the mesa buried layer 7 including the Fe-doped semi-insulating InP first buried layer 7a, the n-type InP second buried layer 7b, and the Fe-doped semi-insulating InP third buried layer 7c is crystal-grown by MOCVD so as to cover both side surfaces of the mesa structure 6 (second crystal growth step).

After the mesa buried layer 7 is crystal-grown, the stripe-shaped SiO₂ mask 22 is removed by wet etching using hydrofluoric acid as an etchant.

The p-type InP second cladding layer 8 and the p-type InGaAs contact layer 9 are sequentially crystal-grown on the top surface of the mesa structure 6 and the surface and the part of the side surfaces of the mesa buried layer 7 by MOCVD (third crystal growth step). FIG. 6 shows a cross-sectional view of each layer after crystal growth.

After the third crystal growth step, a stripe-shaped SiO₂ mask in the (011) direction is formed in a 5 μm wide region including the mesa structure 6 by photolithography technique and etching technique, and wet etching using hydrogen bromide (HBr) as an etchant is performed to etch a portion of the epitaxially crystal-grown layers unnecessary for laser operation in the mesa buried layer 7 until the portion reaches the n-type InP substrate 1. Thereafter, the stripe-shaped SiO₂ mask is removed by wet etching using hydrofluoric acid as an etchant.

Further, a SiO₂ insulation film is formed on the entire surface of the wafer, and a 3 μm wide opening is formed in the SiO₂ insulation film 21 at a position corresponding to the upper side of the mesa structure 6 on the p-type InGaAs contact layer 9 by photolithography technique and dry etching technique. The p-side electrode 31 is formed so as to be in contact with the surface of the p-type InGaAs contact layer 9 in the opening, and the n-side electrode 32 is formed on the rear surface of the n-type InP substrate 1 (electrode formation step).

Through the above-described manufacturing steps, the basic structure of the semiconductor laser, which is an example of the optical semiconductor element 100, is completed.

### Effects of Embodiment 1

According to the optical semiconductor element and the method for manufacturing the same of Embodiment 1, of the mesa buried layer 7 consisting of three layers, the third buried layer 7c in contact with the p-type InP second cladding layer 8 is composed of the semi-insulating InP layer doped with a transition metal, so that the p-n junction is not formed between the semi-insulating InP third buried layer 7c and the p-type InP second cladding layer 8, which enables prevention of the p-n junction capacitance. Furthermore, the current leakage components can be reduced by suppressing the carrier recombination at the interface between the semi-insulating InP third buried layer 7c and the p-type InP second cladding layer 8, thus the operating bandwidth of the optical semiconductor element can be expanded and the light emission efficiency can be improved. In addition, it is possible to easily manufacture the optical semiconductor element having the wide operating bandwidth and the high light emission efficiency.

### COMPARATIVE EXAMPLE

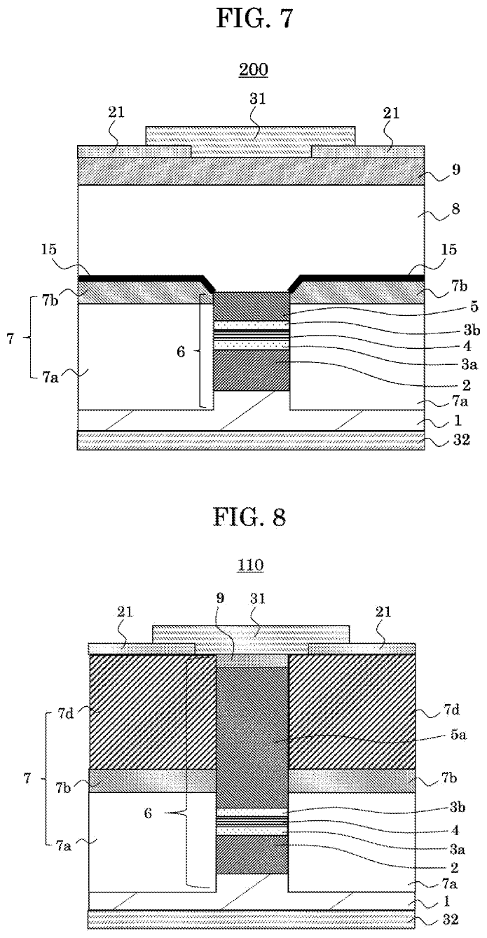

FIG. 7 is a cross-sectional view of an optical semiconductor element 200 as a comparative example. The structural difference from the optical semiconductor element 100 according to Embodiment 1 is that the mesa buried layer 7 of the optical semiconductor element 100 according to Embodiment 1 is composed of three layers of the Fe-doped semi-insulating InP first buried layer 7a, the n-type InP second buried layer 7b, and the Fe-doped semi-insulating InP third buried layer 7c, whereas the optical semiconductor element 200 of the comparative example has a two-layer structure of the Fe-doped semi-insulating InP first buried layer 7a and the n-type InP second buried layer 7b, that is, there is no Fe-doped semi-insulating InP third buried layer 7c.

In the optical semiconductor element 200 as the comparative example, the n-type InP second buried layer 7b and the p-type InP second cladding layer 8 are in contact with each other. Consequently, a p-n junction region 15 is formed at the interface therebetween. The n-type InP second buried layer 7b forms a barrier against holes existing in the p-type InP second cladding layer 8. This is because although Fe doped in the Fe-doped semi-insulating InP first buried layer 7a acts as acceptors for trapping electrons in InP, Fe has no trapping effect on holes, so that the barrier against holes existing in the p-type InP second cladding layer 8 is required.

In the element structure of the optical semiconductor element 200 according to the comparative example, the p-n junction region 15 having a large area exists at the interface between the n-type InP second buried layer 7b and the p-type InP second cladding layer 8, whereby there is a problem that the cut-off frequency decreases. When the cut-off frequency decreases, there is a problem that the operating bandwidth of the optical semiconductor element 200 is limited in applications requiring high-speed operation such as optical communication. In addition, the carrier recombination in the p-n junction region 15 increases the current leakage and thus the light emission efficiency decreases.

### Embodiment 2

FIG. 8 is a cross-sectional view of an element structure of an optical semiconductor element 110 according to Embodiment 2. The optical semiconductor element 110 according to Embodiment 2 including: an n-type InP substrate 1 (a first-conductivity-type semiconductor substrate); a stripe-shaped mesa structure 6 including a laminate of an n-type InP cladding layer 2 (a first-conductivity-type cladding layer), a first optical confinement layer 3a, an active layer 4, a second optical confinement layer 3b, a p-type InP first cladding layer 5a (a second-conductivity-type first cladding layer), a p-type InGaAs contact layer 9 (a second-conductivity-type contact layer), which are sequentially laminated on the n-type InP substrate 1, and a part of the n-type InP substrate 1; a mesa buried layer 7 including a semi-insulating InP first buried layer 7a (a semi-insulating first buried layer), an n-type InP second buried layer 7b (a first-conductivity-type second buried layer), and a semi-insulating InP third buried layer 7d (a semi-insulating third buried layer), which are formed on both side surfaces of the mesa structure 6 on the n-type InP substrate 1; a p-side electrode 31 (a second-conductivity-type-side electrode) which is in contact with the p-type InGaAs contact layer 9 through an opening of an insulation film 21 formed on a top surface of the mesa structure 6 and a surface of the mesa buried layer 7; and an n-side electrode 32 (a first-conductivity-type-side electrode) formed on a rear surface of the n-type InP substrate 1.

The n-type InP cladding layer 2, the first optical confinement layer 3a, the active layer 4, the second optical confinement layer 3b, the p-type InGaAs contact layer 9, the semi-insulating InP first buried layer 7a, and the n-type InP second buried layer 7b have the same layer thicknesses, dopants, and doping concentrations as those of the optical semiconductor element 100 according to Embodiment 1.

The p-type InP cladding layer 5a is doped with Zn. A typical layer thickness of the p-type InP cladding layer 5a is 2.3 μm and a typical doping concentration of Zn is 1.0×10¹⁸ cm⁻³.

The semi-insulating InP third buried layer 7d is doped with transition metals. Specific examples of the transition metal include Fe, Ru, and Ti or the like. A typical layer thickness of the semi-insulating InP third buried layer 7d is 2.0 μm and a typical doping concentration of transition metals is 5.0×10¹⁶ cm⁻³.

Characteristics of the element structure of the optical semiconductor element 110 according to Embodiment 2 will be described.

In the optical semiconductor element 110 according to Embodiment 2, the semi-insulating InP third buried layer 7d is in contact with only both side surfaces of the p-type InP cladding layer 5a of the mesa structure 6. Consequently, the contact area between the semi-insulating InP third buried layer 7d and the p-type InP cladding layer 5a is much smaller than the contact area between the semi-insulating InP third buried layer 7c and the p-type InP second cladding layer 8 in the optical semiconductor element 100 according to Embodiment 1.

When the contact area between the semi-insulating InP third buried layer 7d and the p-type InP cladding layer 5a is small, it is possible to suppress the area of a region in the semi-insulating InP third buried layer 7d that changes from semi-insulating to p-type due to diffusion of Zn, which is a dopant of the p-type InP cladding layer 5a, into the semi-insulating InP third buried layer 7d by heat treatment during crystal growth of the semi-insulating InP third buried layer 7d.

Furthermore, the presence of the n-type InP second buried layer 7b provided in the mesa buried layer 7 makes it possible to narrow the path for holes that pass through the semi-insulating InP third buried layer 7d, which has no hole trapping effect, to leak into the n-side region.

Noted that since the volume of the p-type InP cladding layer 5a is smaller than the volume of the p-type InP second cladding layer 8 of the optical semiconductor element 100 according to Embodiment 1, an increase in the element resistance of the optical semiconductor element 110 is unavoidable to some extent.

### A Method for Manufacturing the Optical Semiconductor Element 110 According to Embodiment 2

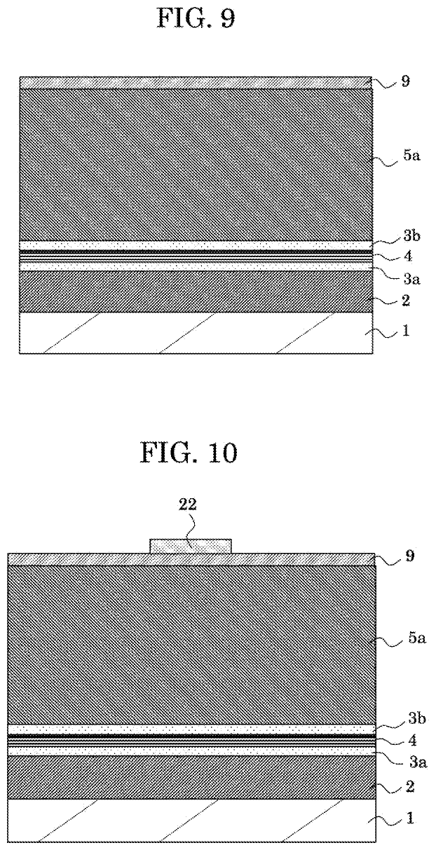

A method for manufacturing the optical semiconductor element 110 according to Embodiment 2 will be described below. The S-doped n-type InP cladding layer 2, the undoped AlGaInAs active layer 4 having upper and lower surfaces sandwiched between the AlGaInAs first optical confinement layer 3a and the AlGaInAs second optical confinement layer 3b, the Zn-doped p-type InP cladding layer 5a, and the Zn-doped p-type InGaAs contact layer 9 are sequentially crystal-grown on the S-doped n-type InP substrate 1 whose upper surface is the (100) plane (first crystal growth step). FIG. 9 shows a cross-sectional view of each layer after crystal growth.

After the first crystal growth step, a SiO₂ film is formed on the surface of the p-type InGaAs contact layer 9. Examples of the method for forming the SiO₂ include a CVD method or the like. After the formation of the SiO₂ film, as shown in the cross-sectional view of FIG. 10, the SiO₂ film is patterned into a stripe-shaped SiO₂ mask 22 in the (011) direction by photolithography technique and etching technique. The width of The SiO₂ mask 22 is, for example, 1.5 μm.

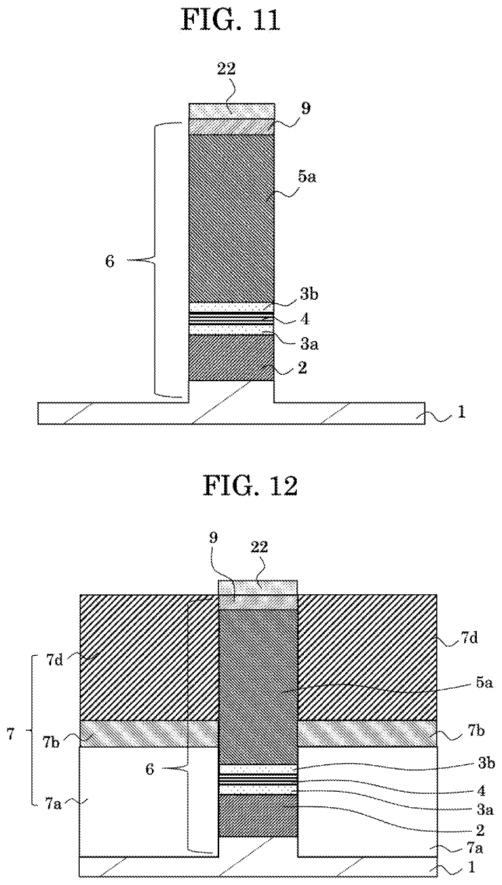

Next, as shown in the cross-sectional view of FIG. 11, the stripe-shaped SiO₂ mask 22 is used as an etching mask to perform dry etching from the p-type InGaAs contact layer 9 to the middle of the n-type InP substrate 1, thereby forming the stripe-shaped mesa structure 6 (mesa structure formation step). A typical height of the mesa structure 6 from the surface of the n-type InP substrate 1 is 4.0 μm. Here, the etching mask is not limited to the SiO₂ mask 22 but may be a SiN mask. The etching is not limited to dry etching, and wet etching may be used.

After the stripe-shaped mesa structure 6 is formed, as shown in the cross-sectional view of FIG. 12, the mesa buried layer 7 including the Fe-doped semi-insulating InP first buried layer 7a, the S-doped n-type InP second buried layer 7b, and the Fe-doped semi-insulating InP third buried layer 7d is crystal-grown by MOCVD so as to cover both side surfaces of the mesa structure 6 (second crystal growth step).

After the mesa buried layer 7 is crystal-grown, the stripe-shaped SiO₂ mask 22 is removed by wet etching using hydrofluoric acid as an etchant.

After the second crystal growth step, a stripe-shaped SiO₂ mask in the (011) direction is formed in a 5 μm wide region including the structure 6 mesa by photolithography technique and etching technique, and wet etching using HBr as an etchant is performed to etch a portion of the epitaxially crystal-grown layers unnecessary for laser operation in the mesa buried layer 7 until the portion reaches the n-type InP substrate 1. Thereafter, the stripe-shaped SiO₂ mask is removed by wet etching using hydrofluoric acid as an etchant.

Furthermore, a SiO₂ insulation film is formed on an entire surface of a wafer, and a 3 μm wide opening is formed in the SiO₂ insulation film 21 at a position corresponding to the upper side of the mesa structure 6 on the p-type InGaAs contact layer 9 and the Fe-doped semi-insulating InP third buried layer 7d by photolithography technique and dry etching technique. A p-side electrode 31 is formed so as to be in contact with the surface of the p-type InGaAs contact layer 9 through the opening, and an n-side electrode 32 is formed on the rear surface of the n-type InP substrate 1 (electrode formation step).

Through the above-described manufacturing steps, the basic structure of the semiconductor laser, which is an example of the optical semiconductor element 110, is completed.

The number of crystal growth cycles in the method for manufacturing the optical semiconductor element 100 according to Embodiment 1 requires three. On the other hand, in the method for manufacturing the optical semiconductor element 110 according to Embodiment 2, as described above, the number of crystal growth cycles requires two, which is one less than that in Embodiment 1. In addition, the number of heat treatment cycles for crystal growth after the formation of the Zn-doped p-type InP cladding layer is smaller than that in Embodiment 1.

Therefore, according to the method for manufacturing the optical semiconductor element 110 of Embodiment 2, it is easier to prevent Fe-doped semi-insulating InP third buried layer 7d from becoming p-type due to diffusion of Zn in the Zn-doped p-type InP cladding layer 5a as compared with the case of Embodiment 1.

### Effects of Embodiment 2

According to the optical semiconductor element and the method for manufacturing the same of Embodiment 2, since the semi-insulating InP third buried layer 7d is in contact with the p-type InP cladding layer 5a only on both side surfaces of the mesa structure 6, the contact area between the semi-insulating InP third buried layer 7d and the p-type InP cladding layer 5a can be greatly reduced, whereby it is possible to more effectively prevent the carrier recombination. As a result, the operating bandwidth of the optical semiconductor element is further expanded and the light emission efficiency is further improved. In addition, such a high-performance optical semiconductor element can be easily manufactured.

### Embodiment 3

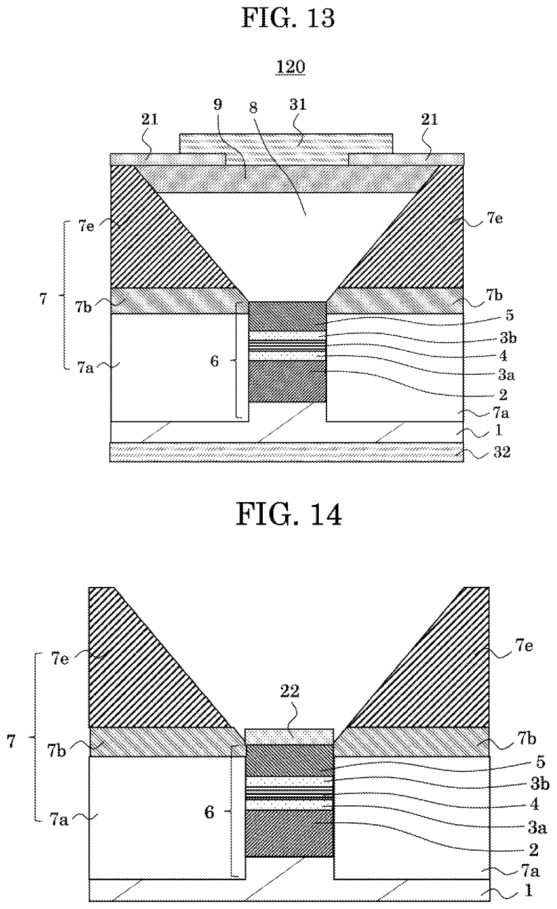

FIG. 13 is a cross-sectional view of an element structure of an optical semiconductor device 120 according to Embodiment 3. The optical semiconductor element 120 according to Embodiment 3 including: an n-type InP substrate 1 (a first-conductivity-type semiconductor substrate); a stripe-shaped mesa structure 6 including a laminate of an n-type InP cladding layer 2 (a first-conductivity-type cladding layer), a first optical confinement layer 3a, an active layer 4, a second optical confinement layer 3b, a p-type InP first cladding layer 5 (a second-conductivity-type first cladding layer), which are sequentially laminated on the n-type InP substrate 1, and a part of the n-type InP substrate 1; a mesa buried layer 7 including a semi-insulating InP first buried layer 7a (a semi-insulating first buried layer), an n-type InP second buried layer 7b (a first-conductivity-type second buried layer), and a semi-insulating InP third buried layer 7e (a semi-insulating third buried layer), which are formed on both side surfaces of the mesa structure 6 on the n-type InP substrate 1 and has a shape of side surfaces extending in a tapered shape from the top surface of the mesa structure 6; a p-type InP second cladding layer 8 (a second-conductivity-type second cladding layer) and a p-type InGaAs contact layer 9 (a second-conductivity-type contact layer), which are formed so as to bury a top surface of the mesa structure 6 and the side surfaces of the mesa buried layer 7 which extends in the tapered shape; a p-side electrode 31 (a second-conductivity-type-side electrode), which is in contact with the p-type InGaAs contact layer 9 through an opening of the insulation film 21 formed on a surface of the p-type InGaAs contact layer 9; and an n-side electrode 32 (a first-conductivity-type-side electrode) formed on a rear surface of the n-type InP substrate 1.

The n-type InP cladding layer 2, the first optical confinement layer 3a, the active layer 4, the second optical confinement layer 3b, the p-type InP first cladding layer 5, the p-type InP second cladding layer 8, the p-type InGaAs contact layer 9, the semi-insulating InP first buried layer 7a, and the n-type InP second buried layer 7b have the same layer thicknesses, dopants, and doping concentrations as those of the optical semiconductor element 100 according to Embodiment 1.

The semi-insulating InP third buried layer 7e is doped with transition metals. Specific examples of the transition metal include Fe, Ru, and Ti. A typical layer thickness of the semi-insulating InP third buried layer 7e is 2.0 μm and a typical doping concentration of the transition metals is 5.0×10¹⁶ cm⁻³.

Characteristics of the element structure of the optical semiconductor device 120 according to Embodiment 3 will be described.

In the optical semiconductor device 120 according to Embodiment 3, the side surfaces of the semi-insulating InP third buried layer 7e on the mesa structure 6 side have a tapered shape extending from the top surface of the mesa structure 6. The p-type InP second cladding layer 8 is in contact with the semi-insulating InP third buried layer 7e only at both side surfaces extending in the tapered shape. Consequently, the contact area between the semi-insulating InP third buried layer 7e and the p-type InP second cladding layer 8 is much smaller than the contact area between the semi-insulating InP third buried layer 7c and the p-type InP second cladding layer 8 in the optical semiconductor element 100 according to Embodiment 1.

Since the contact area between the semi-insulating InP third buried layer 7e and the p-type InP second cladding layer 8 is small, it is possible to suppress the area of a region in the semi-insulating InP third buried layer 7e that changes from semi-insulating to p-type due to diffusion of Zn, which is a dopant of the p-type InP second cladding layer 8, into the semi-insulating InP third buried layer 7e by heat treatment during the crystal growth of the semi-insulating InP third buried layer 7e.

Furthermore, the presence of the n-type InP second buried layer 7b provided in the mesa buried layer 7 makes it possible to narrow the path for holes that pass through the semi-insulating InP third buried layer 7e, which has no hole trapping effect, to leak into the n-side region.

In the optical semiconductor device 120 according to Embodiment 3, since the p-type InP second cladding layer 8 is formed so as to bury the semi-insulating InP third buried layer 7e whose side surfaces have the tapered shape extending from the top surface of the mesa structure 6, the p-type InP second cladding layer 8 has a tapered shape extending from the top surface of the mesa structure 6 to a surface thereof. The angle between both tapered side surfaces and the surface of the n-type InP substrate 1 is set to 50° or more and 60° or less.

Consequently, the volume of the p-type InP second cladding layer 8 of the optical semiconductor device 120 according to Embodiment 3 is larger than the volume of the p-type InP cladding layer 5a of the optical semiconductor element 110 according to Embodiment 2. Therefore, the element resistance of the optical semiconductor element 120 according to Embodiment 3 is lower than the element resistance of the optical semiconductor element 110 according to Embodiment 2.

### A Method for Manufacturing the Optical Semiconductor Element 120 According to Embodiment 3

A method for manufacturing the optical semiconductor element 120 according to Embodiment 3 will be described below.

The steps up to the formation of the mesa structure 6 are the same as the manufacturing steps shown in FIGS. 2 to 4 showing the method for manufacturing the optical semiconductor element 100 according to Embodiment 1, and thus description thereof is omitted.

After the stripe-shaped mesa structure 6 is formed, as shown in the cross-sectional view of FIG. 14, the mesa buried layer 7 including the Fe-doped semi-insulating InP first buried layer 7a, the n-type InP second buried layer 7b, and the Fe-doped semi-insulating InP third buried layer 7e is crystal-grown by MOCVD so as to cover both side surfaces of the mesa structure 6 (second crystal growth step).

The typical thickness of the Fe-doped semi-insulating InP third buried layer 7e is 2.0 μm, which is thicker than the typical thickness of 0.5 μm of the Fe-doped semi-insulating InP third buried layer 7c in Embodiment 1. The total typical thickness of the mesa buried layer 7 is 4.0 μm, which is 2.0 μm higher than the typical height of 2.0 μm of the mesa structure 6 from the surface of the n-type InP substrate 1. Consequently, when the Fe-doped semi-insulating InP third buried layer 7e of the mesa buried layer 7 is crystal-grown, the crystal-grown surface is located higher than the top surface of the mesa structure 6.

Although the thickness of the mesa buried layer 7 is set to be larger than the height of the mesa structure 6 as described above, if the crystal growth temperature is 500° C. to 650° C. and the V/III ratio is about 30 to 200, which are general crystal growth conditions of the MOCVD, the mesa buried layer 7 crystal-grows from the top surface of the mesa structure 6 as a starting point so as to widen the opening while exposing the (110) B plane on both side surfaces of the mesa buried layer 7. That is, as shown in the cross-sectional view of FIG. 14, the opposite side surfaces of the Fe-doped semi-insulating InP third buried layer 7e extend in the tapered shape as the crystal grows. Since the tapered side surfaces are the (111) B planes, the angle between the tapered side surfaces and the surface of the n-type InP substrate 1 which is the (100) plane is in the range of 50° to 60°.

After the mesa buried layer 7 is crystal-grown, the stripe-shaped SiO₂ mask 22 is removed by wet etching using hydrofluoric acid as an etchant.

The p-type InP second cladding layer 8 and the p-type InGaAs contact layer 9 are sequentially crystal-grown on the top surface of the mesa structure 6 and the tapered side surfaces of the mesa buried layer 7 by MOCVD (third crystal growth step). FIG. 15 shows a cross-sectional view of each of the layers after the crystal growth.

After the third crystal growth step, a stripe-shaped SiO₂ mask in the (011) direction is formed in a 5 μm wide region including the mesa by structure 6 photolithography technique and etching technique, and wet etching using HBr as an etchant is performed to etch a portion of the epitaxially crystal-grown layers unnecessary for laser operation in the mesa buried layer 7 until the portion reaches the n-type InP substrate 1. Thereafter, the stripe-shaped SiO₂ mask is removed by wet etching using hydrofluoric acid as an etchant.

Further, a SiO₂ insulation film is formed on the entire surface of the wafer, and a 3 μm wide opening is formed in the SiO₂ insulation film 21 at a position corresponding to the upper side of the mesa structure 6 on the p-type InGaAs contact layer 9 by photolithography technique and dry etching technique. The p-side electrode 31 is formed so as to be in contact with the surface of the p-type InGaAs contact layer 9 in the opening, and the n-side electrode 32 is formed on the rear surface of the n-type InP substrate 1 (electrode formation step).

Through the above-described manufacturing steps, the basic structure of the semiconductor laser, which is an example of the optical semiconductor element 120, is completed.

### Effects of Embodiment 3

According to the optical semiconductor element and the method for manufacturing the same of Embodiment 3, since the p-type InP second cladding layer 8 is in contact with the semi-insulating InP third buried layer 7e only at the tapered side surfaces thereof, the contact area between the semi-insulating InP third buried layer 7e and the p-type InP second cladding layer 8 can be greatly reduced, whereby it is possible to more effectively prevent the carrier recombination. In addition, the volume of the p-type InP second cladding layer 8 becomes larger. Therefore, the element resistance is small, the operating bandwidth of the optical semiconductor element is further expanded and the light emission efficiency is further improved. In addition, such a high-performance optical semiconductor element can be easily manufactured.

### Embodiment 4

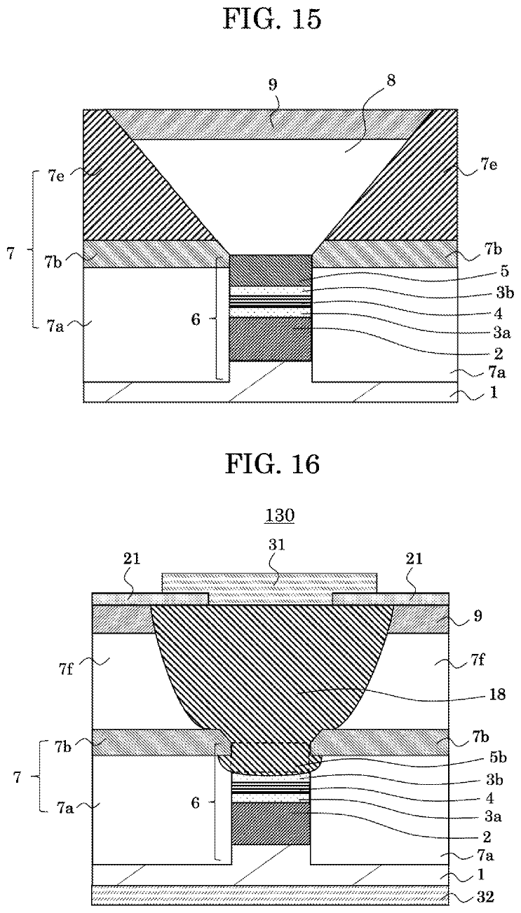

FIG. 16 is a cross-sectional view of an element structure of an optical semiconductor element 130 according to Embodiment 4. The optical semiconductor element 130 according to Embodiment 4 including: an n-type InP substrate 1 (a first-conductivity-type semiconductor substrate); a stripe-shaped mesa structure 6 including a laminate of an n-type InP cladding layer 2 (a first-conductivity-type cladding layer), a first optical confinement layer 3a, an active layer 4, a second optical confinement layer 3b, a p-type InP first cladding layer 5b (a second-conductivity-type first cladding layer), which are sequentially laminated on the n-type InP substrate 1, and a part of the n-type InP substrate 1; a mesa buried layer 7 including a semi-insulating InP first buried layer 7a (a semi-insulating first buried layer) and an n-type InP second buried layer 7b (a first-conductivity-type second buried layer), which are formed on both side surfaces of the mesa structure 6 on the n-type InP substrate 1; a semi-insulating cladding layer 7f and a p-type InGaAs contact layer 9 (a second-conductivity-type contact layer), which are formed so as to cover a top surface of the mesa structure 6 and a surface and a part of both side surfaces of the mesa buried layer 7; a Zn-diffused p-type conversion region 18 (a second-conductivity-type dopant diffused region) formed in the p-type InGaAs contact layer 9, the semi-insulating InP cladding layer 7f, and the p-type InP cladding layer 5b, and extending from a surface of the p-type InGaAs contact layer 9 to the p-type InP cladding layer 5b; a p-side electrode 31 (a second-conductivity-type-side electrode) which is in contact with the p-type InGaAs contact layer 9 through an opening of an insulation film 21 formed on a surface of the p-type InGaAs contact layer 9; and an n-side electrode 32 (a first-conductivity-type-side electrode) formed on a rear surface of the n-type InP substrate 1.

The n-type InP cladding layer 2, the first optical confinement layer 3a, the active layer 4, the second optical confinement layer 3b, the p-type InGaAs contact layer 9, the semi-insulating InP first buried layer 7a, and the n-type InP second buried layer 7b have the same layer thicknesses, dopants, and doping concentrations as those of the optical semiconductor element 100 according to Embodiment 1.

The p-type InP cladding layer 5b is doped with Zn. A typical layer thickness of the p-type InP cladding layer 5b is 0.3 μm, and a typical doping concentration of Zn is 1.0×10¹⁸ cm⁻³.

The semi-insulating InP cladding layer 7f is doped with transition metals. Specific examples of the transition metal include Fe, Ru, and Ti. A typical layer thickness of the semi-insulating InP cladding 7f is 2.0 μm and a typical doping concentration of transition metals is 5.0×10¹⁶ cm⁻³.

Characteristics of the element structure of the optical semiconductor element 130 according to Embodiment 4 will be described.

In the optical semiconductor device 130 according to Embodiment 4, as described above, the Zn-diffused p-type conversion region 18, which is formed inside the p-type InP cladding layer 5b, the p-type InGaAs contact layer 9, and the semi-insulating InP cladding layer 7f, and extends from the surface of the p-type InGaAs contact layer 9 to the p-type InP cladding layer 5b, is provided. The tip portion of the Zn-diffused p-type conversion region 18 may reach the second optical confinement layer 3b or the active layer 4.

The Zn-diffused p-type conversion region 18 in the semi-insulating InP cladding layer 7f is converted from the original semi-insulating property to the p-type, and thus substantially functions as a p-type InP cladding layer. The Zn-diffused p-type conversion region 18 is formed in a vapor-phase diffusion step performed after completion of all crystal growth steps, as will be described later. Consequently, in the step after the Zn-diffused p-type conversion region 18 is formed, there is no heat treatment at such a high temperature as to diffuse Zn, so that it is possible to suppress the Fe-doped semi-insulating InP first buried layer 7a from becoming p-type due to further diffusion of Zn.

In addition, since the volume of the p-type InP cladding layer formed by the Zn-diffused p-type conversion region 18 is larger than that in Embodiment 2, the element resistance can be further reduced.

### A method for manufacturing the optical semiconductor element 130 according to Embodiment 4

A method for manufacturing the optical semiconductor element 130 according to Embodiment 4 will be described below. The steps up to the formation of the mesa structure 6 are the same as the manufacturing steps shown in FIGS. 2 to 4 showing the method for manufacturing the optical semiconductor element 100 according to Embodiment 1, and thus description thereof is omitted.

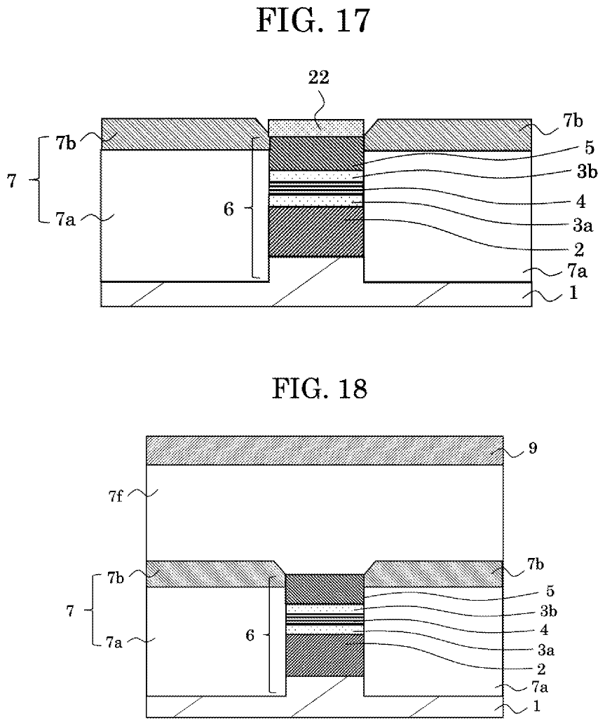

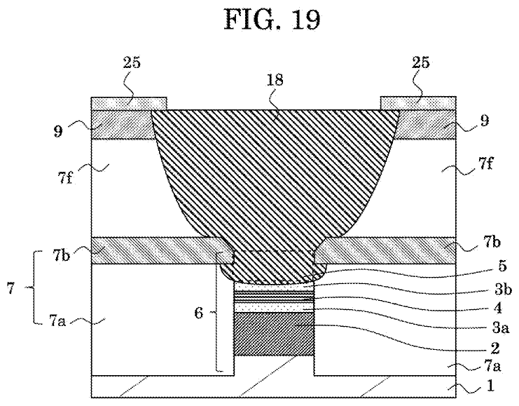

After the stripe-shaped mesa structure 6 is formed, as shown in the cross-sectional view of FIG. 17, the mesa buried layer 7 including the Fe-doped semi-insulating InP first buried layer 7a and the n-type InP second buried layer 7b is crystal-grown by MOCVD so as to cover both side surfaces of the mesa structure 6 (second crystal growth step).

After the mesa buried layer 7 is crystal-grown, the stripe-shaped SiO₂ mask 22 is removed by wet etching using hydrofluoric acid as an etchant.

The semi-insulating InP cladding layer 7f and the p-type InGaAs contact layer 9 are sequentially crystal-grown on the top surface of the mesa structure 6 and a surface and a part of both side surfaces of the mesa buried layer 7 by MOCVD (third crystal growth step). FIG. 18 shows a cross-sectional view of each of the layers after the crystal growth.

A SiO₂ film 25 is formed on the surface of the wafer, and a stripe-shaped opening in the (011) direction is formed by photolithography technique and etching technique. The width of the opening is 2 μm. The SiO₂ film 25 functions as a diffusion mask.

Zn is diffused in a region from the p-type InGaAs contact layer 9 exposed in the opening to the part of the p-type InP cladding layer 5b by a vapor phase diffusion method in the MOCVD apparatus to form a Zn-diffused p-type conversion region 18 in the p-type InGaAs contact layer 9, the semi-insulating InP cladding layer 7f and the p-type InP cladding layer 5b (dopant diffusion step). The region in which Zn is diffused inside the semi-insulating InP cladding layer 7f becomes p-type, and thus functions as a p-type InP cladding layer. The tip portion of the Zn-diffused p-type conversion region 18 may reach the second optical confinement layer 3b or the active layer 4.

After the dopant diffusion step, a stripe-shaped SiO₂ mask in the (011) direction is formed in a 5 μm wide region including the mesa structure 6 by photolithography technique and etching technique, and wet etching using HBr as an etchant is performed to etch a portion of the epitaxially crystal-grown layers unnecessary for laser operation in the mesa buried layer 7 until the portion reaches the n-type InP substrate 1. Thereafter, the stripe-shaped SiO₂ mask is removed by wet etching using hydrofluoric acid as an etchant.

Furthermore, a SiO₂ insulation film is formed on the entire surface of the wafer, and a 3 μm wide opening is formed in the SiO₂ insulation film 21 at a position corresponding to the upper side of the mesa structure 6 on the p-type InGaAs contact layer 9 by photolithography technique and dry etching technique. The p-side electrode 31 is formed so as to be in contact with the surface of the p-type InGaAs contact layer 9 through the opening, and the n-side electrode 32 is formed on the rear surface of the n-type InP substrate 1 (electrode formation step).

Through the above-described manufacturing steps, the basic structure of the semiconductor laser, which is an example of the optical semiconductor element 130, is completed.

### Effects of Embodiment 4

According to the optical semiconductor element and the method for manufacturing the same of Embodiment 4, the region where Zn is diffused in the semi-insulating InP cladding layer 7f functions as the p-type InP cladding layer, and the p-type InP cladding layer conversion region and the semi-insulating InP cladding layer 7f are in contact with each other only at both side surfaces. Therefore, the contact area between the semi-insulating InP third buried layer 7f and the p-type InP cladding layer conversion region can be greatly reduced, whereby it is possible to more effectively prevent the carrier recombination. In addition, the volume of the p-type InP cladding layer conversion region becomes larger. Therefore, in the optical semiconductor element, the element resistance is small, the operating bandwidth is further expanded, and the light emission efficiency is further improved. In addition, such a high-performance optical semiconductor element can be easily manufactured.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type InP substrate (first-conductivity-type semiconductor substrate)
2 n-type InP cladding layer (first-conductivity-type cladding layer)
3a first optical confinement layer
3b second optical confinement layer
4 active layer
5 p-type InP first cladding layer (second-conductivity-type first cladding layer)
5a, 5b p-type InP cladding layer (second-conductivity-type first cladding layer)
6 mesa structure
7 mesa buried layer
7a semi-insulating InP first buried layer (semi-insulating first buried layer)
7b n-type InP second buried layer (first-conductivity-type second buried layer)
7c, 7d, 7e semi-insulating InP third buried layer (semi-insulating third buried layer)
7f semi-insulating InP cladding layer (semi-insulating cladding layer)
8 p-type InP second cladding layer (second-conductivity-type second cladding layer)
9 p-type InGaAs contact layer (second-conductivity-type contact layer)
15 p-n junction region
18 Zn-diffused p-type conversion region (dopant diffused second-conductivity-type region)
21 insulation film
22 SiO₂ mask
25 SiO₂ film
31 p-side electrode (second-conductivity-type-side electrode)
32 n-side electrode (first-conductivity-type-side electrode)
100, 110, 120, 130, 200 optical semiconductor element

1. An optical semiconductor element comprising:
an n-type InP semiconductor substrate;
a stripe-shaped mesa structure including a laminate of an n-type InP cladding layer, an active layer, and a p-type InP first cladding layer layered on the n-type InP semiconductor substrate; and
a mesa buried layer including a semi-insulating InP first buried layer, an n-type InP second buried layer adjacent to the semi-insulating InP first buried layer, and a semi-insulating InP third buried layer which is adjacent to the n-type InP second buried layer and is doped with a transition metal, which are sequentially formed on both side surfaces of the mesa structure on the n-type InP semiconductor substrate.

2. The optical semiconductor element according to claim 1, further comprising a p-type InP second cladding layer formed on a top surface of the mesa structure and a surface and a part of the side surfaces of the mesa buried layer.

3. The optical semiconductor element according to claim 2, wherein
a layer thickness of the semi-insulating InP third buried layer is thicker than one or both of a layer thickness of a depletion layer formed by the n-type InP second buried layer and the semi-insulating InP third buried layer and a layer thickness of a depletion layer formed by the semi-insulating InP third buried layer and the p-type InP second cladding layer.

4. The optical semiconductor element according to claim 1, further comprising a p-type InP second cladding layer formed on the top of the mesa structure and both sides of the mesa buried layer that tapers to reach the surface, wherein
an angle between both tapered side surfaces and the surface of the first-conductivity-type semiconductor substrate is 50° or more and 60° or less.

5. An optical semiconductor element comprising:
a first-conductivity-type semiconductor substrate;
a stripe-shaped mesa structure including a laminate of a first-conductivity-type cladding layer, an active layer, a second-conductivity-type first cladding layer, a second-conductivity-type second cladding layer, and a second-conductivity-type contact layer layered on the first-conductivity-type semiconductor substrate; and
a mesa buried layer including a semi-insulating first buried layer, a first-conductivity-type second buried layer, and a semi-insulating third buried layer doped with a transition metal, which are sequentially formed on both side surfaces of the mesa structure on the first-conductivity-type semiconductor substrate, wherein
a top surface of the mesa structure and a surface of the semi-insulating third buried layer form the same plane.

6. An optical semiconductor element comprising:
an n-type InP semiconductor substrate;
a stripe-shaped mesa structure including a laminate of an n-type InP cladding layer, an active layer, and a p-type InP first cladding layer layered on the n-type InP semiconductor substrate;
a mesa buried layer including a semi-insulating InP first buried layer and an n-type InP second buried layer adjacent to the semi-insulating InP first buried layer, which are formed on both side surfaces of the mesa structure on the n-type InP semiconductor substrate;
a semi-insulating InP cladding layer doped with a transition metal, the semi-insulating InP cladding layer being formed on a top surface of the mesa structure and at least a surface of the n-type InP second buried layer;
a p-type contact layer formed on the semi-insulating InP cladding layer; and
a p-type dopant diffused region formed in the second-conductivity-type the p-type contact layer, the semi-insulating InP cladding layer, and at least a part of the p-type InP first cladding layer.

7. The optical semiconductor element according to claim 1, wherein
the transition metal is any one of Fe, Ru, and Ti or a combination of two or more thereof, and the semi-insulating InP first buried layer is doped with Fe.

8. The optical semiconductor element according to claim 5, wherein
the first-conductivity-type semiconductor substrate, the first-conductivity-type cladding layer, the second-conductivity-type first cladding layer, and the mesa buried layer are all made of InP, and the active layer is made of a material containing at least In and Ga.

9. The optical semiconductor element according to claim 5, wherein
the first-conductivity-type is n-type, and the second-conductivity-type is p-type.

10. The optical semiconductor element according to claim 1, further comprising a first optical confinement layer which contacts with one surface of the active layer on the side of the n-type InP semiconductor substrate, and a second optical confinement layer which contacts with the other surface of the active layer.

11. The optical semiconductor element according to claim 1, wherein
the mesa structure further includes a part of the n-type InP semiconductor substrate.

12-19. (canceled)

20. The optical semiconductor element according to claim 5, wherein
the transition metal is any one of Fe, Ru, and Ti or a combination of two or more thereof, and the semi-insulating InP first buried layer is doped with Fe.

21. The optical semiconductor element according to claim 6, wherein
the transition metal is any one of Fe, Ru, and Ti or a combination of two or more thereof, and the semi-insulating InP first buried layer is doped with Fe.

22. The optical semiconductor element according to claim 5, further comprising a first optical confinement layer which contacts with one surface of the active layer on the side of the n-type InP semiconductor substrate, and a second optical confinement layer which contacts with the other surface of the active layer.

23. The optical semiconductor element according to claim 6, further comprising a first optical confinement layer which contacts with one surface of the active layer on the side of the n-type InP semiconductor substrate, and a second optical confinement layer which contacts with the other surface of the active layer.

24. The optical semiconductor element according to claim 2, wherein
the semi-insulating InP third buried layer has a two layer structure, which has an Fe-doped layer provided on the n-type InP second buried layer side, and a Ru-doped or Ti-doped layer provided on the p-type InP second cladding layer side.
